(19) United States
(12) Patent Application Publication
(10) Pub. No.: US 2026/0040995 A1
(43) Pub. Date: Feb. 5, 2026

(54) PACKAGE LID ADHESION AND SEAL ENHANCEMENTS

(71) Applicant: MACOM Technology Solutions Holdings, Inc., Lowell, MA (US)

(72) Inventors: Sung Chul Joo, Lowell, MA (US); Daniel Rowland, Morgan Hill, CA (US); Alexander Komposch, Morgan Hill, CA (US); Abel Anzualda, Gilroy, CA (US)

(21) Appl. No.: 18/792,193

(22) Filed: Aug. 1, 2024

(51) Int. Cl. H01L 23/10; H01L 23/04

(52) U.S. Cl. CPC H01L 23/10; H01L 23/04

(57) ABSTRACT

Semiconductor device packages with lids having features for enhanced adhesion and seal to package frames are described. An example package includes a flange having a top surface, a frame integrated with or secured over the top surface of the flange, and a lid secured over the frame. The lid includes a peripheral detent surface extending along a peripheral side surface of the lid in one example. The lid also includes an interference interlock surface extending around an edge of the peripheral detent surface in other examples. The detent surface, interlock surface, and related features help to position and secure the lid over the frame of the package, providing additional surface areas for contact, mechanical interlock, adhesive grip, and other adhesion and sealing mechanisms. The enhancements result in lids that exhibit enhanced adhesion to and seal with package frames, even after temperature cycling.

### BACKGROUND

Various types of packages are available for integrated semiconductor devices, including digital and analog integrated circuits, power transistor amplifiers, and related devices. The packages can both protect and secure the components and provide electrically conductive leads for electrical couplings to the integrated semiconductor devices. Example package types include surface mount, through-hole mount, flange mount, flat package, chip carrier, pin grid array, and chip-scale packages, and other packaging formats are known in the field. The type, size, lead style, structure, materials, and other characteristics of a package can be selected based on the type of components being housed within the package, as well as the application for the components. Certain packages can be more or less suitable for components used in high power and high frequency applications.

### SUMMARY

Semiconductor device packages with lids having features for enhanced adhesion and seal to package frames are described. An example semiconductor device package includes a frame and a lid secured over the frame. Another example package includes a flange having a top surface, a frame integrated with or secured over the top surface of the flange, and a lid secured over the frame. The lid includes a peripheral detent surface extending along a peripheral side surface of the lid.

The lid also includes an interference interlock surface extending around an edge of the peripheral detent surface in some examples. The interference interlock surface extends substantially perpendicular to a bottom surface of the lid in one example. The interference interlock surface extends substantially perpendicular to a bottom surface of the lid and the peripheral detent surface in other examples. The interference interlock surface extends substantially perpendicular to a bottom surface of the lid and the peripheral detent surface, and the interference interlock surface faces an inner surface of the frame in still other examples. The interference interlock surface extends at an angle with respect to the peripheral side surface of the lid in some other examples. The interference interlock surface can be an angled interlock surface extending around an edge of the peripheral detent surface in those examples.

In other aspects, the package can include an adhesive between the peripheral detent surface and a top surface of the frame. The package can include an adhesive between the peripheral detent surface and a top surface of the frame and between the interference interlock surface and the inner surface of the frame in other examples.

The lid further includes a ridge ring extending around the peripheral detent surface in some cases. The ridge ring includes an interference interlock surface extending around an edge of the peripheral detent surface. The lid further includes a standoff ring in some examples. The peripheral detent surface is positioned at an end of the standoff ring in that case.

In other aspects, the lid also includes a first orientation marker formed in or on a top surface of the lid and a second orientation marker formed in or on a bottom surface of the lid. The first orientation marker includes a first style of marker and the second orientation marker comprises a second style of marker.

The detent surface, interlock surface, and related features help to position and secure the lid over the frame of the package, providing additional surface areas for contact, mechanical interlock, adhesive grip, and other adhesion and sealing mechanisms. The enhancements result in lids that exhibit enhanced adhesion to and seal with package frames, even after temperature cycling.

### BRIEF DESCRIPTION OF THE DRAWINGS

Aspects of the present disclosure can be better understood with reference to the following drawings. It is noted that the elements in the drawings are not necessarily to scale, with emphasis instead being placed upon clearly illustrating the principles of the embodiments. In the drawings, like reference numerals designate like or corresponding, but not necessarily the same, elements throughout the several views.

FIG. 1 illustrates a perspective view of an example device package according to various embodiments described herein.

FIG. 2A illustrates a bottom perspective view of a lid for the device package shown in FIG. 1 according to various embodiments described herein.

FIG. 2B illustrates a bottom perspective view of another lid for the device package shown in FIG. 1 according to various embodiments described herein.

FIG. 2C illustrates a bottom perspective view of another lid for the device package shown in FIG. 1 according to various embodiments described herein.

FIG. 3A illustrates the sectional view of the device package designated A-A in FIG. 1 with the lid shown in FIG. 2B according to various embodiments described herein.

FIG. 3B is an exploded view of components shown in the detail region in FIG. 3A according to various embodiments described herein.

FIG. 3C is a view of the components shown in the detail region in FIG. 3A according to various embodiments described herein.

FIG. 4A illustrates the sectional view of the device package designated A-A in FIG. 1 with the lid shown in FIG. 2C according to various embodiments described herein.

FIG. 4B is an exploded view of components shown in the detail region in FIG. 4A according to various embodiments described herein.

FIG. 4C is a view of the components shown in the detail region in FIG. 4A according to various embodiments described herein.

FIG. 5A is an exploded detail view of another lid for the device package shown in FIG. 1 according to various embodiments described herein.

FIG. 5B is another detail view of the lid and device package shown in FIG. 5A according to various embodiments described herein.

FIG. 6A illustrates the sectional view of the device package designated A-A in FIG. 1 with another lid according to various embodiments described herein.

FIG. 6B is an exploded view of components shown in the detail region in FIG. 6A according to various embodiments described herein.

FIG. 6C is a view of the components shown in the detail region in FIG. 6A according to various embodiments described herein.

### DETAILED DESCRIPTION

A number of different packages are available for electrical components, including devices formed on semiconductor die. The type, size, lead style, and materials of any given package can be chosen based on the type of electrical components housed within the package, as well as the application for the components and related concerns. Example package types include surface-mount, chip carrier, pin grid array, flat package, ball grid array, multi-chip, and chip-scale packages, among others. Other types of small-pin-count packages (e.g., “TO” packages) are known for packaging individual transistors, diodes, and related electrical components. The packages can both protect and secure the components and provide electrically conductive leads for the components.

Packages including air cavities are also used for semiconductor devices used for high power and frequency applications, because dielectric capacitances can be minimized, among other benefits. Air cavity packages can include leads and be mounted on PCBs, in through holes of PCBs, and in other configurations. Some packages are more suitable for components used in high power and high frequency applications, and the type, size, lead style, structure, materials, and other characteristics of packages can be selected and designed based on the types of components being housed within them, as well as the application for the components.

Device packages can be subject to relatively harsh environmental and working conditions over time. Device packages and the devices within the packages can be subject to a range of different environmental conditions, mechanical stresses and forces, and related factors. Temperature cycling can lead to thermal stresses, as one example, such as stresses due to thermal expansion mismatches between package frames and lids or covers. Delamination of the adhesives or adhesion means between package frames and lids can result from thermal stresses due to temperature cycling. Similarly, the movement or separation of the surfaces, the formation of cracks or misalignments, and related problems can occur between package frames and lids due to temperature cycling and for other reasons. These and related problems can result in package failures.

In the context outlined above, semiconductor device packages with lids having features for enhanced adhesion and seal to package frames are described. An example package includes a flange having a top surface, a frame integrated with or secured over the top surface of the flange, and a lid secured over the frame. The lid includes a peripheral detent surface extending along a peripheral side surface of the lid in one example. The lid also includes an interference interlock surface extending around an edge of the peripheral detent surface in other examples. The detent surface, interlock surface, and related features help to position and secure the lid over the frame of the package, providing additional surface areas for contact, mechanical interlock, adhesive grip, and other adhesion and sealing mechanisms. The enhancements result in lids that exhibit enhanced adhesion to and seal with package frames, even after temperature cycling.

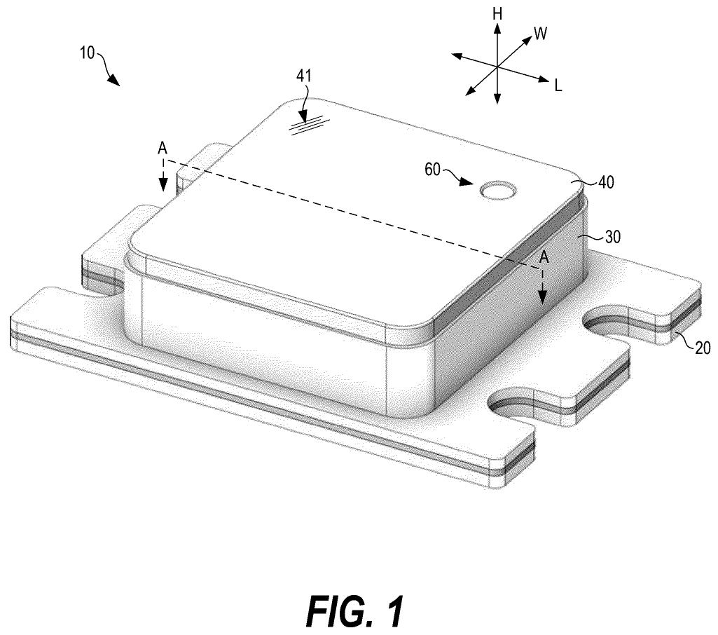

Turning to the drawings, FIG. 1 illustrates a perspective view of an example device package 10 (also “package 10”). The package 10 is depicted as a representative example. The package 10 is not drawn to scale, and other packages consistent with the concepts described herein can vary in shape and/or size as compared to that shown. For example, the length “L,” width “W,” and height “H” of the package 10 can vary among the embodiments. The package 10 is an example of one type of package in which the concepts of package lid or cover adhesion enhancements can be implemented. The concepts are not limited to use or incorporation with the package 10 shown in FIG. 1, as the concepts can be extended to use with a wide range of semiconductor device packages.

The package 10 includes a flange 20, a frame 30 over the flange 20, and a lid 40 secured over the frame 30. An air cavity is formed within the package 10. The air cavity is bounded by an inner top surface of the flange 20, an inner surface of the frame 30, and a bottom surface of the lid 40. One or more semiconductors devices, including semiconductor die and related components, can be secured within the package 10. Because the devices and components within the air cavity are not surrounded by (i.e., in contact with) package molding materials, they are not subject to electrical effects due to the materials (e.g., parasitic capacitances, etc.).

The semiconductor devices in the package 10 can be electrically coupled to conductive leads or surfaces within the package 10 using wire bonds, direct couplings (e.g., direct contact, soldering, sintering, conductive epoxy, etc.), or other means. The conductive leads of the package 10 can extend through the flange 20, so that electrical couplings can be made between the package 10 and the devices in the package 10, as would be understood in the field of device packaging.

The flange 20 can be embodied by conductive materials, insulating materials, or a combination of conductive and insulating materials. The flange 20 can include a conductive slug of metal(s) with or without plating in some cases. In some cases, the flange 20 can be embodied as a composite core of conductive metal or metal alloy with other materials or particles distributed in the metal or metal alloy. The flange 20 can also be formed from insulative materials, such as ceramics, polymers, liquid crystal polymers (LCPs), or polymer blends, with or without glass, carbon, or other reinforcements, among other insulative materials. The flange 20 can also be embodied as a combination of conductive and insulative materials. The flange 20 is not limited to being formed from any particular materials, as a range of materials are known and used in device packages.

The flange 20 can serve in part as or include one or more conductive leads for the package 10 in some cases. As one example, a semiconductor device die including a metal layer on the bottom surface of the die can be electrically coupled to the top surface of the flange 20 within the package 10. The flange 20 can act as a type of lead for the package 10 in that case. In other cases, the flange 20 can act as a heat sink but not an electrical contact.

The frame 30 is formed as a type of square ring with rounded corners having a central opening in the example shown. The frame 30 can also be formed in other shapes, including rectangular, circular, and other shapes with central openings. The frame 30 can be formed integrally or together with the flange 20, in one example, or the frame 30 can be formed separately from and secured to the flange 20. The frame 30 can be formed from ceramics, polymers or polymer blends with or without glass, carbon, or other reinforcements, and other materials. The frame 30 is not limited to being formed from any particular materials, as a range of materials are known and used in device packages. The frame 30 can be formed using materials selected to provide protection (e.g., protection against temperatures, vibration, moisture, and other conditions) for the components in the package 10, mechanical strength, matching of the thermal expansion as compared to other materials in the package 10, and other relevant factors.

The frame 30 includes an open central region, which encircles the air cavity formed between a top surface of the flange 20, the inner periphery of the frame 30, and the underside of the lid 40 in the package 10. The flange 20 and the frame 30 can be secured together to create a seal between them if not formed integrally. The bottom surface of the frame 30 can be secured to the top surface of the flange 20 using an adhesive, such as epoxy or another adhesive, using mechanical interlocks or interferences, using fasteners, or combinations thereof. In other cases, the bottom surface of the frame 30 can be secured to the top surface of the flange 20 by welding, heating, brazing or soldering.

The lid 40 can be formed from plastic, ceramic, glass, or related materials. The materials used for the lid 40 can be selected to provide protection against vibrations, moisture, and other conditions for the components in the package 10, mechanical strength, adequate matching of the thermal expansion as compared to other materials in the package 10, and other relevant factors. The lid 40 can be secured over the frame 30 using a range of different approaches, and a top surface 41 of the lid 40 is visible in FIG. 1. For example, the lid 40 can be secured over the frame 30 as shown in FIG. 1 using an acrylic or epoxy resin cured by ultraviolet (UV) light, chemical reaction, or other suitable approach. The lid 40 can also be secured over the frame 30 using other approaches in some cases, such as using adhesives, welding, melting, or other adhesion means, using mechanical interlocks or interferences, using fasteners, or combinations thereof. The lid 40 can be secured over the frame 30 to create a hermetic (or near hermetic) seal for the package 10 in some cases depending on the materials used to form the flange 20, the frame 30, and the lid 40. The package 10 can be a hermetically sealed package in some cases.

As noted above, the package 10 is depicted as an example package in which the concepts of package lid or cover adhesion enhancements can be implemented. The package 10 can be relied upon to for packaging one or more radio frequency (RF) power amplifiers for wireless communications applications, as one example. Such power amplifiers can be embodied as power transistors formed in Gallium Nitride (GaN) material(s), as one example, but the amplifiers within the package 10 are not limited to any particular type or technology of semiconductor materials. The package 10 is also not limited to packaging RF power amplifiers, as the package 10 can be used for packaging a range of different devices.

It is important that the lid 40 is securely fitted and attached to the frame 30 with a good seal between them to protect the amplifiers or other devices within the package 10. The lid 40 should also remain sufficiently secured to the frame 30 even after significant temperature cycling of the package 10. Temperature cycling can lead to stresses between the frame 30 and the lid 40 due to thermal expansion mismatches and related effects. Delamination of the adhesives or adhesion means between the frame 30 and the lid 40 can result from the thermal stresses due to temperature cycling. Similarly, the movement or separation of the surfaces, the formation of cracks or misalignments, and related problems can occur between the frame 30 and the lid 40 due to thermal expansion mismatches and related effects. These and related problems can result in failure of the package 10 and particularly a failure for the lid 40 to remain securely fitted and attached to the frame 30 with a good seal between them. A torsion or torque test applied to the lid 40, as one example, can fail at an unacceptably high rate due to delamination or cracks that form in the adhesion layer between the frame 30 and the lid 40 after temperature cycling.

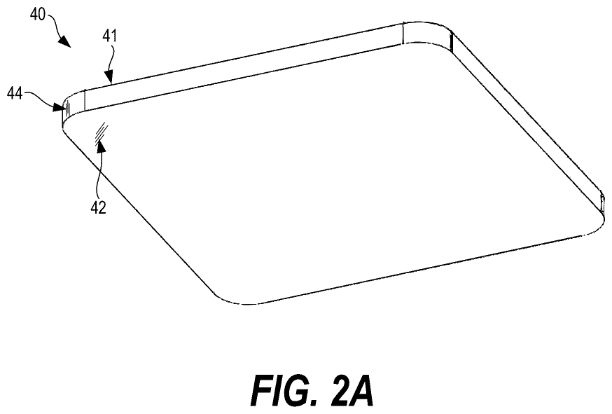

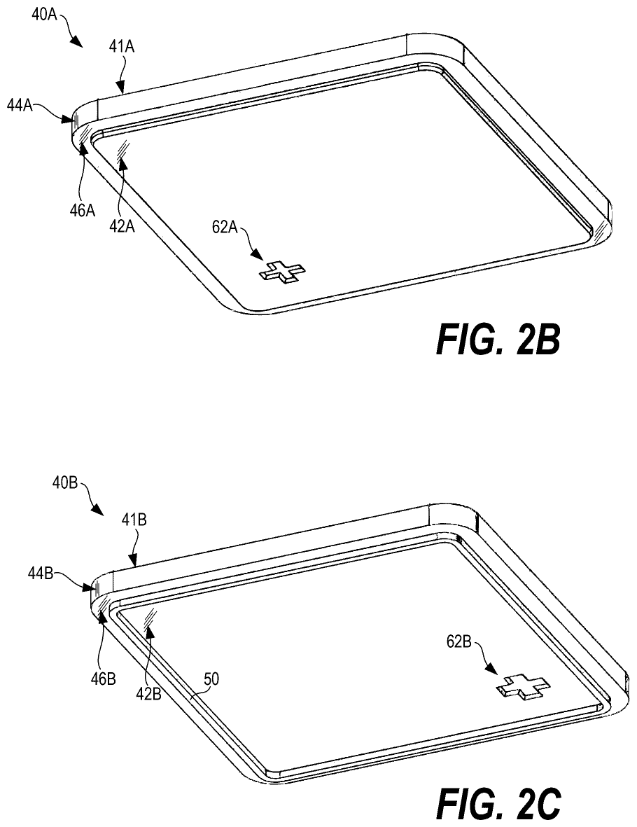

FIG. 2A illustrates a bottom perspective view of the lid 40 for the package 10 shown in FIG. 1. The lid 40 includes a top surface 41 (see FIG. 1), a bottom surface 42, and a peripheral side surface 44. The peripheral side surface 44 extends around a periphery of the lid 40 between the top surface 41 and the bottom surface 42. The lid 40 also includes an orientation marker 60 (see FIG. 1) proximate to a certain (i.e., a single) corner of the lid 40. The orientation marker 60 is formed as a circular depression in or on the top surface 41 of the lid and provides an external visual indicator of the orientation of the package 10. In other cases, the orientation marker 60 can be printed, etched, or otherwise formed as a circle or another shape in or on the top surface 41. The orientation marker 60 can be relied upon to identify pins, contacts, and other features of the package 10 based on the position of the orientation marker 60.

The bottom surface 42 of the lid 40 is flat and does not include any detents, detent surfaces, or other mechanical interlocks or related features. The bottom surface 42 of the lid 40 is placed directly over the top surface of the frame 30 when the package 10 is assembled. An adhesive can also be positioned between the bottom surface 42 of the lid 40 and the top surface of the frame 30 to secure the lid 40 to the frame 30. More particularly, the adhesive can be applied to the bottom surface 42 of the lid 40, the top surface of the frame 30, or to both the bottom surface 42 of the lid 40 and the top surface of the frame 30. Then, the bottom surface 42 of the lid 40 can be placed directly over the top surface of the frame 30 to assemble the package 10.

Evaluation and testing has identified that the lid 40 may not be sufficiently attached to the frame 30 in all cases after temperature cycling. Delamination of the adhesives or adhesion means between the frame 30 and the lid 40 has resulted after temperature cycling in some cases. Similarly, the movement or separation of the surfaces, the formation of cracks or misalignments, and related problems can occur between the frame 30 and the lid 40 due to thermal expansion mismatches and related effects. These and related problems can result in failure of the package 10 and particularly a failure for the lid 40 to remain securely fitted and attached to the frame 30 with a good seal between them. A torsion or torque test applied to the lid 40, as one example, can fail at an unacceptably high rate due to delamination or cracks that form in the adhesion layer between the frame 30 and the lid 40 after temperature cycling.

FIG. 2B illustrates a bottom perspective view of another lid 40A for the package 10 shown in FIG. 1 according to various embodiments described herein. The lid 40A includes features for enhanced adhesion to the frame 30 of the package 10. The lid 40A includes a top surface 41A, a bottom surface 42A, and a peripheral side surface 44A. The peripheral side surface 44A extends around a periphery of the lid 40A between the top surface 41A and the bottom surface 42A.

The lid 40A also includes an orientation marker 62A formed in or on the bottom surface 42A of the lid 40A. The orientation marker 62A is formed as a plus-shaped depression in the bottom surface 42A in the example depicted and provides a visual indicator of the orientation of the lid 40A. In other cases, the orientation marker 62A can be printed, etched, or otherwise formed as a plus or another shape in or on the top surface 41. The orientation marker 62A can be relied upon for automated picking and placing of the lid 40A over the frame 30 in some cases. Although not visible in FIG. 2B, the lid 40A can also include the orientation marker 60 on the top surface 41A of the lid 40A. The shapes or styles of the orientation markers 60 and 62A are preferably different than each other to distinguish them from each other using computer-aided image processing techniques, for example, as part of an automated workflow. The orientation markers 60 and 62A can be located proximate to a corresponding (i.e., the same) corner of the lid 40A in one example. However, in other cases, the orientation marker 60 can be located proximate to a first corner of the lid 40A, and the orientation marker 62A can be located proximate to a second corner of the lid 40A different than the first corner.

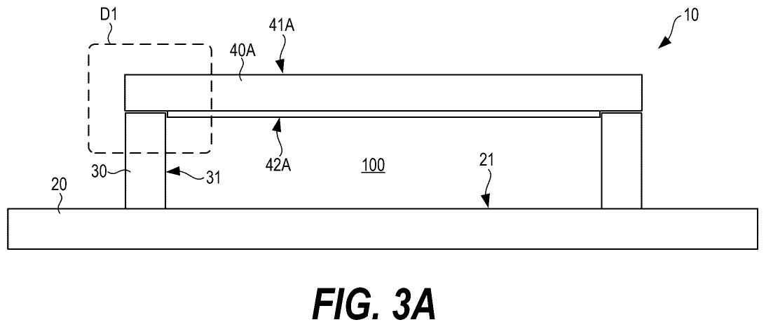

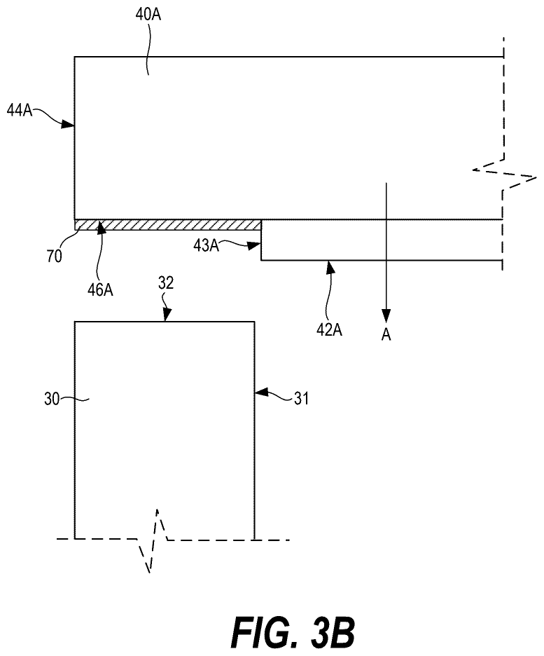

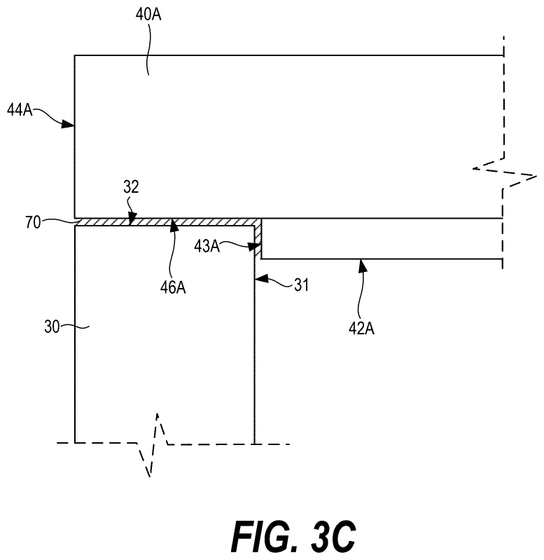

The lid 40A also includes a peripheral detent surface 46A. The outer edge of the peripheral detent surface 46A extends along the peripheral side surface 44A of the lid 40A. The peripheral detent surface 46A extends in a plane that is separated from and parallel to the bottom surface 42A. The peripheral detent surface 46A also extends in a plane that is substantially perpendicular to the peripheral side surface 44A of the lid 40A. As described in further detail below with reference to FIG. 3B, the lid 40A also includes an interference interlock surface that extends around an inner edge of the peripheral detent surface 46A. The interference interlock surface helps to position and secure the lid 40A over the frame 30. The interference interlock surface also provides a type of mechanical interlock with the frame 30 to help hold the lid 40A in place. Adhesive can also be applied between the interference interlock surface and the inner surfaces of the frame 30 to help secure the lid 40A in place. These and other aspects of the lid 40A are described below.

FIG. 2C illustrates a bottom perspective view of another lid 40B for the package 10 shown in FIG. 1 according to various embodiments described herein. The lid 40B includes features for enhanced adhesion to the frame 30 of the package 10. The lid 40B includes a top surface 41B, a bottom surface 42B, and a peripheral side surface 44B. The peripheral side surface 44B extends around a periphery of the lid 40B between the top surface 41B and the bottom surface 42B. The lid 40B also includes an orientation marker 62B, which is formed in the bottom surface 42B. The orientation marker 62B provides a visual indicator of the orientation of the lid 40B, which can be relied upon for automated picking and placing of the lid 40B over the frame 30.

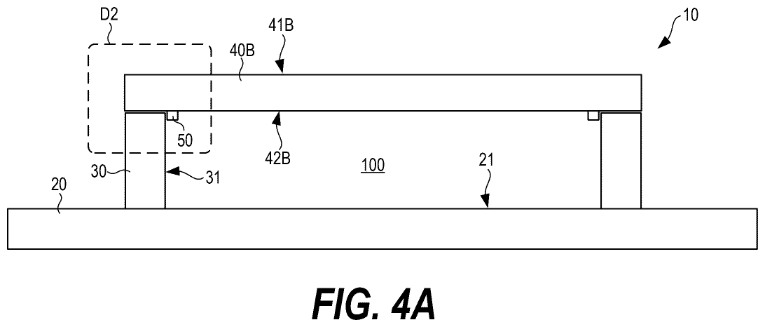

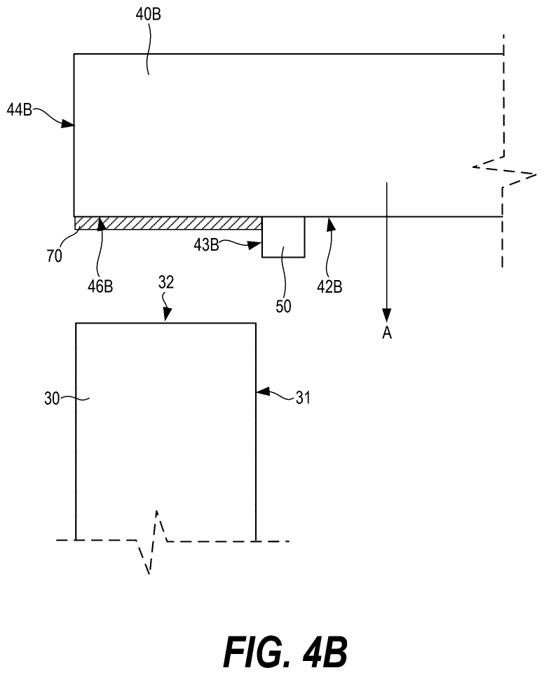

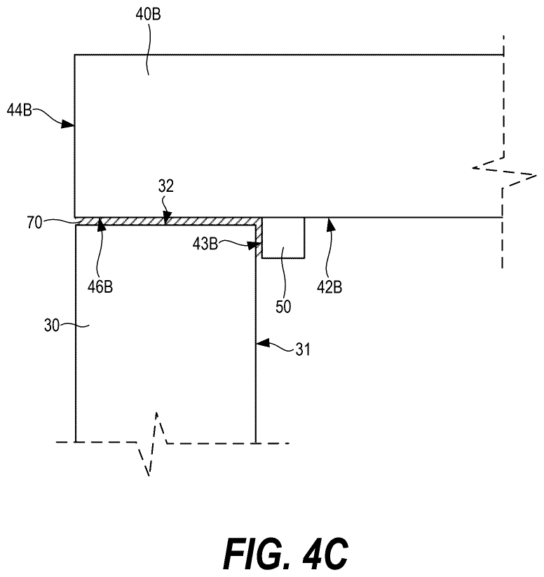

The lid 40B also includes a peripheral detent surface 46B. The outer edge of the peripheral detent surface 46B extends along the peripheral side surface 44B of the lid 40B. The peripheral detent surface 46B extends in a plane that is separated from and parallel to the bottom surface 42B. The peripheral detent surface 46B also extends in a plane that is substantially perpendicular to the peripheral side surface 44B of the lid 40B. As described in further detail below with reference to FIG. 4B, the lid 40B also includes a ridge ring 50. The ridge ring 50 extends around the peripheral detent surface 46B. More particularly, an interference interlock surface on one side of the ridge ring 50 extends around an inner edge of the peripheral detent surface 46B. The ridge ring 50 helps to position and secure the lid 40B over the frame 30. The ridge ring 50 also provides a type of mechanical interlock with the frame 30 to help hold the lid 40A in place. Adhesive can also be applied between the interference interlock surface of the ridge ring 50 and the inner surfaces of the frame 30 to help secure the lid 40B in place. These and other aspects of the lid 40B are described below.

FIG. 3A illustrates the sectional view of the package 10 designated A-A in FIG. 1 with the lid 40A shown in FIG. 2B over secured over the frame 30. The package 10 includes the flange 20, the frame 30 over the flange 20, and the lid 40A secured over the frame 30. An air cavity 100 is formed within the package 10. The air cavity 100 is bounded by a top surface 21 of the flange 20, an inner surface 31 of the frame 30, and the bottom surface 42A of the lid 40A. One or more semiconductors devices, including semiconductor die and related components, can be secured within the package 10.

FIG. 3B is an exploded view of components shown in the detail region “D1” in FIG. 3A, and FIG. 3C is a view of the detail region “D1” in FIG. 3A. Referring first to FIG. 3B, the lid 40A is shown above the frame 30. The peripheral detent surface 46A of the lid 40A is positioned over the top surface 32 of the frame 30. The lid 40A also includes an interference interlock surface 43A. The interference interlock surface 43A extends along an inner edge of the peripheral detent surface 46A. The interference interlock surface 43A helps to position and secure the lid 40A over the frame 30. The interference interlock surface 43A provides a type of mechanical interlock in connection with the inner surface 31 of the frame 30, to help hold the lid 40A in place. The lid 40A can be lowered in the direction “A” shown in FIG. 3B, so that the peripheral detent surface 46A rests upon the top surface 32 of the frame 30.

An adhesive 70 can also be positioned between the peripheral detent surface 46A of the lid 40A and the top surface 32 of the frame 30 to secure the lid 40A to the frame 30. The adhesive 70 is applied to the peripheral detent surface 46A of the lid 40A in the example shown in FIG. 3B. In other cases, the adhesive 70 can be applied to the top surface 32 of the frame 30, or the adhesive 70 can be applied to both the peripheral detent surface 46A and the top surface 32. Then, the lid 40A can be placed directly over and upon the frame 30 to assemble the package 10. Particularly, the lid 40A can be lowered in the direction “A” shown in FIG. 3B, so that the peripheral detent surface 46A rests upon the top surface 32 of the frame 30, with the adhesive 70 being positioned between them.

Referring to FIG. 3C, the lid 40A is shown positioned on and secured over the frame 30, as in FIG. 3A. FIG. 3C also illustrates how the adhesive 70 is positioned between the peripheral detent surface 46A and the top surface 32 of the frame 30. The adhesive 70 is also positioned (e.g., has extended between) between the interference interlock surface 43A of the lid 40A and the inner surface 31 of the frame 30. The interference interlock surface 43A helps to position and secure the lid 40A over the frame 30. The interference interlock surface 43A provides a type of mechanical interlock in connection with the inner surface 31 of the frame 30. The interference interlock surface 43A particularly provides a type of mechanical interlock against rotational or twisting forces applied to the lid 40A because the interference interlock surface 43A faces the inner surface 31 of the frame 30.

FIG. 4A illustrates the sectional view of the package 10 designated A-A in FIG. 1 with the lid 40B shown in FIG. 2C over secured over the frame 30. The package 10 includes the flange 20, the frame 30 over the flange 20, and the lid 40B secured over the frame 30. An air cavity 100 is formed within the package 10. The air cavity 100 is bounded by a top surface 21 of the flange 20, an inner surface 31 of the frame 30, and the bottom surface 42B of the lid 40B. One or more semiconductors devices, including semiconductor die and related components, can be secured within the package 10.

FIG. 4B is an exploded view of components shown in the detail region “D2” in FIG. 4A, and FIG. 4C is a view of the detail region “D2” in FIG. 4A. Referring first to FIG. 4B, the lid 40B is shown above the frame 30. The peripheral detent surface 46B of the lid 40B is positioned over the top surface 32 of the frame 30. The lid 40B also includes a ridge ring 50. The ridge ring 50 extends around the peripheral detent surface 46B. An interference interlock surface 43B on one side of the ridge ring 50 extends around an inner edge of the peripheral detent surface 46B. The ridge ring 50 helps to position and secure the lid 40B over the frame 30. The ridge ring 50 also provides a type of mechanical interlock with the frame 30 to help hold the lid 40A in place. The lid 40B can be lowered in the direction “A” shown in FIG. 4B, so that the peripheral detent surface 46B rests upon the top surface 32 of the frame 30.

An adhesive 70 can also be positioned between the peripheral detent surface 46B of the lid 40B and the top surface 32 of the frame 30 to secure the lid 40B to the frame 30. The adhesive 70 is applied to the peripheral detent surface 46B of the lid 40B in the example shown in FIG. 3B. In other cases, the adhesive 70 can be applied to the top surface 32 of the frame 30, or the adhesive 70 can be applied to both the peripheral detent surface 46B and the top surface 32. Then, the lid 40B can be placed directly over and upon the frame 30 to assemble the package 10. Particularly, the lid 40B can be lowered in the direction “A” shown in FIG. 4B, so that the peripheral detent surface 46A rests upon the top surface 32 of the frame 30, with the adhesive 70 being positioned between them.

Referring to FIG. 4C, the lid 40B is shown positioned on and secured over the frame 30, as in FIG. 4A. FIG. 4C also illustrates how the adhesive 70 is positioned between the peripheral detent surface 46A and the top surface 32 of the frame 30. The adhesive 70 is also positioned (e.g., has extended between) between the interference interlock surface 43B of the lid 40B and the inner surface 31 of the frame 30. The interference interlock surface 43B helps to position and secure the lid 40B over the frame 30. The interference interlock surface 43B provides a type of mechanical interlock in connection with the inner surface 31 of the frame 30. The interference interlock surface 43B particularly provides a type of mechanical interlock against rotational or twisting forces applied to the lid 40B because the interference interlock surface 43B faces the inner surface 31 of the frame 30.

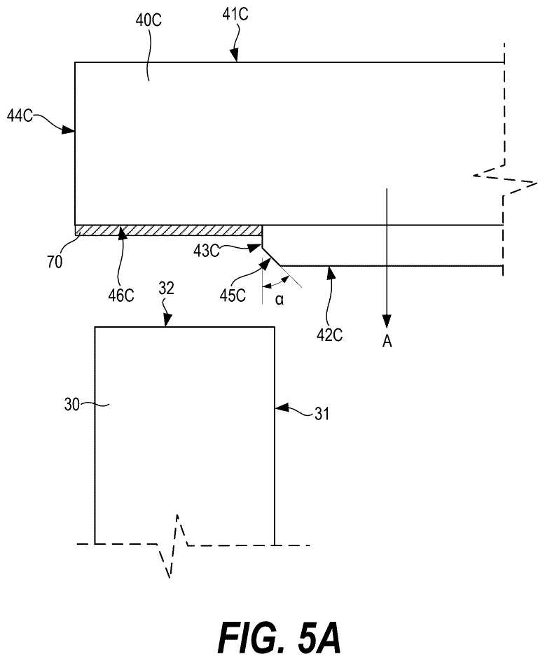

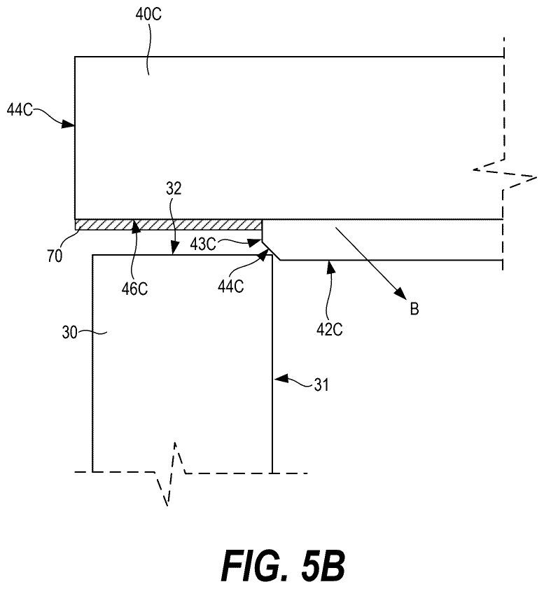

The lids described herein can include additional features that help with positioning. The lids can include interference interlock surfaces with chamfered corners. The chamfered corners are formed by chamfered surfaces at the transitions between the interference interlock surfaces and the bottom surfaces of the lids. FIG. 5A is an exploded detail view of another lid 40C for the package 10 shown in FIG. 1. The lid 40C includes a top surface 41C, a bottom surface 42C, and a peripheral side surface 44C. The peripheral side surface 44C extends around a periphery of the lid 40C between the top surface 41C and the bottom surface 42C. The lid 40C also includes a peripheral detent surface 46C. The outer edge of the peripheral detent surface 46C extends along the peripheral side surface 44C of the lid 40C. The peripheral detent surface 46C extends in a plane that is separated from and parallel to the bottom surface 42C. The peripheral detent surface 46C also extends in a plane that is substantially perpendicular to the peripheral side surface 44C of the lid 40C. The lid 40C also includes an interference interlock surface 43C that extends around an inner edge of the peripheral detent surface 46C.

The lid 40C includes a chamfered corner formed by a chamfered surface 45C. The chamfered surface 45C is positioned at a transition between the interference interlock surface 43C and the bottom surface 42C of the lid 40C. The chamfered surface 45C extends in a plane at an angle of α measured from the interference interlock surface 43C. The angle of α can range from between 30-60 degrees among the embodiments, although smaller and larger angles can be relied upon in some cases. Example values of α include 30, 35, 40, 45, 50, 55, and 60 degrees, with α being 45 degrees and preferred in the example shown.

The adhesive 70 is applied to the peripheral detent surface 46C of the lid 40C in the example shown in FIG. 5A. In other cases, the adhesive 70 can be applied to the top surface 32 of the frame 30, or the adhesive 70 can be applied to both the peripheral detent surface 46C and the top surface 32. Then, the lid 40C can be placed over and upon the frame 30 to assemble the package 10.

The lid 40C is shown above the frame 30 in FIG. 5A. The peripheral detent surface 46C of the lid 40C is positioned over the top surface 32 of the frame 30, but the peripheral detent surface 46C is not directly aligned over the top surface 32. Instead, the peripheral detent surface 46C is offset (e.g., shifted to the right) with respect to the top surface 32 of the frame 30. The lid 40C can be lowered in the direction “A” shown in FIG. 5A, but the peripheral detent surface 46A will not drop directly over the top surface 32 of the frame 30.

FIG. 5B is another detail view of the lid 40C and package 10 shown in FIG. 5A, with the lid 40C lowered further down over the frame 30. As the lid 40C is lowered, the chamfered surface 45C contacts the top corner of the frame 30 between the top surface 32 and the inner surface 31 of the frame 30. With pressure or force applied, the chamfered surface 45C will direct the movement of the lid 40C in the direction “B” shown in FIG. 5B. Movement in the direction “B” will help to align the lid 40C with the frame 30 and align the peripheral detent surface 46C over the top surface 32 of the frame. Thus, the chamfered surface 45C helps to align the lid 40C with the frame 30 during assembly of the package 10. The chamfered surface 45C can be particularly helpful if an automated pick and place system is used to place the lid 40C on the frame 30, because the chamfered surface 45C aligns the lid 40C on the frame 30 in a repeatable way. The lid 40B shown in FIGS. 2C and 4A-4C can also include a chamfered surface similar to the chamfered surface 45C at a corner of the ridge ring 50.

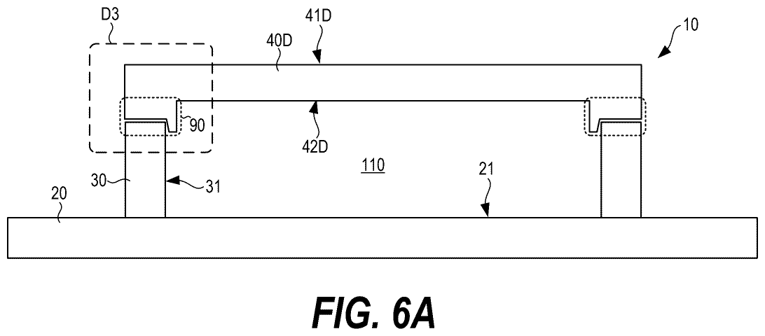

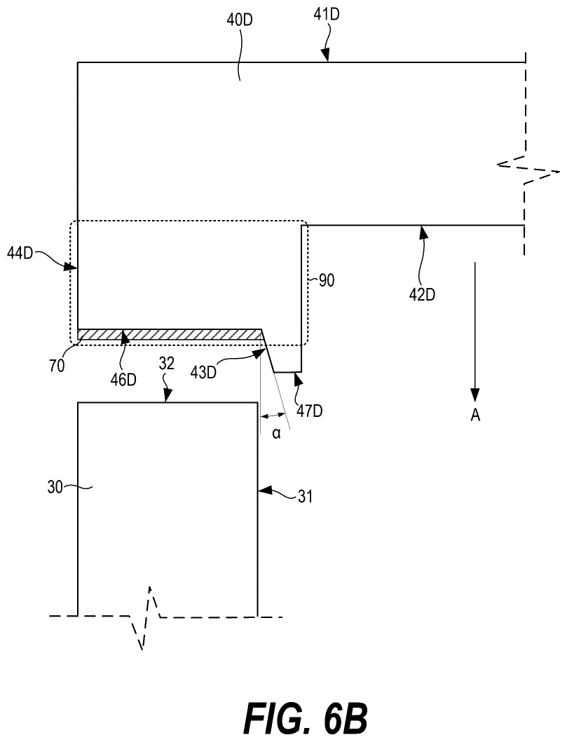

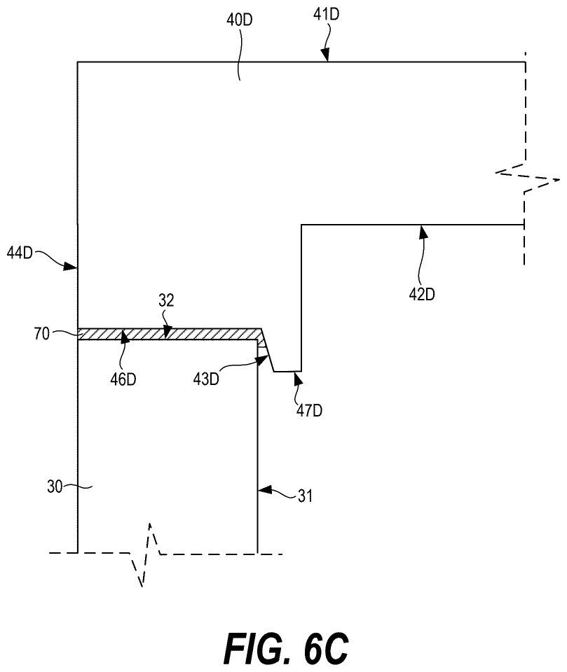

FIG. 6A illustrates the sectional view of the package 10 designated A-A in FIG. 1 with another lid 40D secured over the frame 30. The package 10 includes the flange 20, the frame 30 over the flange 20, and the lid 40D secured over the frame 30. The lid 40D includes a top surface 41D, a bottom surface 42D, and a peripheral side surface 44D. The peripheral side surface 44D extends around a periphery of the lid 40D. The lid 40D also includes a standoff ring 90. The standoff ring 90 extends in a ring around the around a periphery of the lid 40D. An air cavity 110 is formed within the package 10. The air cavity 110 is bounded by a top surface 21 of the flange 20, an inner surface 31 of the frame 30, and the bottom surface 42D of the lid 40D. The air cavity 110 of the package 10 is larger when using the lid 40D than the air cavity 100 of the package 10 when using the lids 40A-40C because of the additional elevation provided by the standoff ring 90.

FIG. 6B is an exploded view of components shown in the detail region “D3” in FIG. 6A. FIG. 6B illustrates the lid 40D over the frame 30 of the package 10. The lid 40D includes a peripheral detent surface 46D at an end of the standoff ring 90. The outer edge of the peripheral detent surface 46D extends along the peripheral side surface 44D of the lid 40D. The peripheral detent surface 46D extends in a plane that is separated from and parallel to the bottom surface 42D. The peripheral detent surface 46D also extends in a plane that is substantially perpendicular to the peripheral side surface 44D of the lid 40D.

The lid 40D also includes an angled interlock surface 43D that extends around an inner edge of the peripheral detent surface 46D. The angled interlock surface 43D extends between the peripheral detent surface 46D and a lower surface 47D of the lid 40C. The angled interlock surface 43D extends in a plane at an angle of α measured from the peripheral side surface 44D of the lid 40D. The angle of α can range from between 30-60 degrees among the embodiments, although smaller and larger angles can be relied upon in some cases. Example values of α include 30, 35, 40, 45, 50, 55, and 60 degrees, with α being 30 degrees in the example shown.

The adhesive 70 is applied to the peripheral detent surface 46D of the lid 40D in the example shown in FIG. 6B. In other cases, the adhesive 70 can be applied to the top surface 32 of the frame 30, or the adhesive 70 can be applied to both the peripheral detent surface 46D and the top surface 32. Then, the lid 40D can be placed over and upon the frame 30 to assemble the package 10.

The lid 40D is shown above the frame 30 in FIG. 6B. The peripheral detent surface 46D of the lid 40D is positioned over the top surface 32 of the frame 30. The lid 40D can be lowered in the direction “A” shown in FIG. 6B. FIG. 6C is another detail view of the lid 40D, with the lid 40D lowered over the top surface 32 of the frame 30. As the lid 40D is lowered, the angled interlock surface 43D may contact the top corner of the frame 30 between the top surface 32 and the inner surface 31 of the frame 30. If so, the angled interlock surface 43D will direct the movement of the lid 40D, align the lid 40D with the frame 30, and align the peripheral detent surface 46D over the top surface 32 of the frame. Thus, the angled interlock surface 43D helps to align the lid 40D with the frame 30 during assembly of the package 10. The angled interlock surface 43D can be particularly helpful if an automated pick and place system is used to place the lid 40D on the frame 30, because the angled interlock surface 43D aligns the lid 40D on the frame 30 in a repeatable way. The lids 40B and 40C can also include angled interlock surfaces similar to the angled interlock surface 43D. For example, the interference interlock surface 43B of the lid 40B can be angled similar to the angled interlock surface 43D in some cases. The interference interlock surface 43C of the lid 40C can also be angled similar to the angled interlock surface 43D in some cases.

The interference interlock surfaces, angled interlock surfaces, interlock surfaces with chamfered corners, and related features described above help to position and secure lids over package frames. Adhesives can also be applied between the interference interlock surfaces and the inner surfaces of the frame to help secure the lids in place. The interference interlock surfaces provide a type of mechanical interlock and help secure the lids against rotational or twisting forces, even after temperature cycling.

Power transistors formed on semiconductor die can be packaged using the device packages described herein. Among other types, the power transistors can be formed as high electron mobility transistors (HEMTs), pseudomorphic high-electron mobility transistors (pHEMTs), metamorphic high-electron mobility transistors (mHEMTs), laterally diffused metal oxide semiconductor transistors (LDMOS), metal-insulator-semiconductor field effect transistors (MISFETs or MISHFETs), metal-oxide-semiconductor field effect transistors (MOSFETs).

The power transistors can be formed using a number of different semiconductor materials and semiconductor manufacturing processes. Example semiconductor materials include the group IV elemental semiconductor materials, including Silicon (Si) and Germanium (Ge), compounds thereof, and the group III elemental semiconductor materials, including Al, Gallium (Ga), Indium (In), and compounds thereof. Semiconductor transistor amplifiers can be constructed from group III-V direct bandgap semiconductor technologies, in certain cases, as the higher bandgaps and electron mobility provided by those devices can lead to higher electron velocity and breakdown voltages, among other benefits. Thus, in some examples, the concepts can be applied to group III-V direct bandgap active semiconductor devices, such as III-Nitride material devices (Aluminum (Al)—, Gallium (Ga)—, Indium (In)—, and their alloys (AlGaIn) based Nitrides), GaAs, InP, InGaP, AlGaAs, etc. devices. However, the principles and concepts can also be applied to transistors and other active devices formed from other semiconductor materials.

As used herein, the term “III-Nitride material(s)” or “Gallium Nitride material(s)” refers to any Group III element-nitride compound. Non-limiting examples of III-nitride materials include Boron Nitride (BN), Aluminum Nitride (AlN), Gallium Nitride (GaN), Indium Nitride (InN), and Thallium Nitride (TIN), as well as any alloys including Group III elements and Group V elements, such as Aluminum Gallium Nitride (AlₓGa₍₁₋ₓ₎N), Indium Gallium Nitride (In_{y}Ga_{(1-y)}N), Aluminum Indium Gallium Nitride (AlₓIn_{y}Ga_{(1-x-y)}N), Gallium Arsenide Phosphide nitride (GaAsₐP_{b}N_{(1-a-b)}), Aluminum Indium Gallium Arsenide Phosphide Nitride (AlₓIn_{y}Ga_{(1-x-y)}ASₐP_{b}N_{(1-a-b)}), among others. Typically, when present, Arsenic and/or Phosphorous are at low concentrations (e.g., less than 5 weight percent). The term “Gallium Nitride” or GaN semiconductor refers directly to gallium nitride, exclusive of its alloys.

According to certain embodiments, the substrates of the semiconductor devices described herein can include Silicon (Si) (i.e., a substrate containing the Si in any form). Examples of substrates comprising Si that can be used in various embodiments include, but are not limited to, SiC substrates, bulk Si wafers, Si-on-insulator (SOI) substrates, Silicon-on-sapphire (SOS) substrates, and separation by implantation of oxygen (SIMOX) substrates, among others. Suitable Silicon substrates also include composite substrates that include a Si wafer bonded to another material such as diamond, AlN, SiC, or other polycrystalline materials. Silicon substrates having different crystallographic orientations can be used, though single crystal silicon substrates can be preferred in certain, but not necessarily all, embodiments. In some embodiments, Silicon (111) substrates are used. A III-Nitride or GaN transistor can be a III-Nitride heterostructure FET (III-N HFET), a metal-insulator-semiconductor FET (MISFET or MISHFET), such as a metal-oxide-semiconductor FET (MOSFET). Alternatively, when implemented as an HFET, III-Nitride transistor can be a HEMT configured to produce a 2DEG.

The features, structures, and characteristics described above may be combined in one or more embodiments in any suitable manner, and the features discussed in the various embodiments are interchangeable in many cases. Although relative terms such as “on,” “below,” “upper,” “lower,” “top,” “bottom,” “right,” and “left” may be used to describe the relative spatial relationships of certain structural features, these terms are used for convenience only, as a direction in the examples. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. are used only as labels, rather than a limitation for a number of the objects.

The terms “about” and “substantially,” unless otherwise defined herein to be associated with a particular range, percentage, or related metric of deviation, account for at least some manufacturing tolerances between a theoretical design and a manufactured product or assembly, such as the geometric dimensioning and tolerancing criteria described in the American Society of Mechanical Engineers (ASME®) Y14.5 and the related International Organization for Standardization (ISO®) standards. Such manufacturing tolerances are also still contemplated even if the “about,” “substantially,” or related terms are not expressly referenced at least in connection with the geometric “perpendicular,” “orthogonal,” “vertex,” “collinear,” “coplanar,” and related terms.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be interpreted to encompass modifications and equivalent structures.

Therefore, the following is claimed:

1. A semiconductor device package, comprising:
a flange comprising a top surface;
a frame integrated with or secured over the flange; and
a lid secured over the frame, the lid comprising a peripheral detent surface extending along a peripheral side surface of the lid.

2. The semiconductor device package according to claim 1, further comprising an adhesive between the peripheral detent surface and a top surface of the frame.

3. The semiconductor device package according to claim 1, wherein the lid further comprises an interference interlock surface extending around an edge of the peripheral detent surface.

4. The semiconductor device package according to claim 3, wherein the interference interlock surface extends substantially perpendicular to a bottom surface of the lid.

5. The semiconductor device package according to claim 3, wherein the interference interlock surface extends substantially perpendicular to a bottom surface of the lid and the peripheral detent surface.

6. The semiconductor device package according to claim 3, wherein:
the interference interlock surface extends substantially perpendicular to a bottom surface of the lid and the peripheral detent surface; and
the interference interlock surface faces an inner surface of the frame.

7. The semiconductor device package according to claim 6, further comprising an adhesive between the peripheral detent surface and a top surface of the frame and between the interference interlock surface and the inner surface of the frame.

8. The semiconductor device package according to claim 3, wherein the interference interlock surface extends at an angle with respect to the peripheral side surface of the lid.

9. The semiconductor device package according to claim 1, wherein the lid further comprises a ridge ring extending around the peripheral detent surface.

10. The semiconductor device package according to claim 9, wherein the ridge ring comprises an interference interlock surface extending around an edge of the peripheral detent surface.

11. The semiconductor device package according to claim 10, wherein the interference interlock surface faces an inner surface of the frame.

12. The semiconductor device package according to claim 11, further comprising an adhesive between the peripheral detent surface and a top surface of the frame and between the interference interlock surface and the inner surface of the frame.

13. The semiconductor device package according to claim 1, wherein the lid further comprises a standoff ring.

14. The semiconductor device package according to claim 13, wherein the peripheral detent surface is positioned at an end of the standoff ring.

15. The semiconductor device package according to claim 14, wherein the lid further comprises an angled interlock surface extending around an edge of the peripheral detent surface.

16. The semiconductor device package according to claim 1, wherein the lid further comprises a first orientation marker formed in or on a top surface of the lid and a second orientation marker formed in or on a bottom surface of the lid.

17. The semiconductor device package according to claim 16, wherein the first orientation marker comprises a first style of marker and the second orientation marker comprises a second style of marker.

18. A semiconductor device package, comprising:
a frame; and
a lid secured over the frame, the lid comprising:
a peripheral detent surface extending along a peripheral side surface of the lid; and
an interference interlock surface extending around an edge of the peripheral detent surface.

19. The semiconductor device package according to claim 18, wherein:
the interference interlock surface extends substantially perpendicular to a bottom surface of the lid and the peripheral detent surface; and
the interference interlock surface faces an inner surface of the frame.

20. The semiconductor device package according to claim 19, further comprising an adhesive between the peripheral detent surface and a top surface of the frame and between the interference interlock surface and the inner surface of the frame.
